(19) United States
(12) Patent Application Publication
(10) Pub. No.: US 2025/0081680 A1
(43) Pub. Date: Mar. 6, 2025

(54) DISPLAY DEVICE

(71) Applicant: LG Display Co., Ltd., Seoul (KR)

(72) Inventors: Hyun Chyol SHIN, Paju-si (KR); Hee Won LEE, Paju-si (KR); Sang Hak SHIN, Paju-si (KR); Jae Kwang LEE, Paju-si (KR); Hyoung Sun PARK, Paju-si (KR); Hyun Seok NA, Paju-si (KR); Seong Soo CHO, Paju-si (KR); Kyeong Min YUK, Paju-si (KR)

(21) Appl. No.: 18/741,433

(22) Filed: Jun. 12, 2024

(30) Foreign Application Priority Data
Sep. 4, 2023 (KR) 10-2023-0116919

(51) Int. Cl. H01L 33/44; H01L 25/16; H01L 33/62

(52) U.S. Cl. CPC H10H 20/84; H01L 25/167; H10H 20/857

(57) ABSTRACT

The present disclosure provides a display device that includes an insulating layer disposed on a substrate. The display device further includes a plurality of first electrodes and contact electrodes disposed on the insulating layer. The display device further includes a plurality of light-emitting elements disposed on the plurality of first electrodes. The display device further includes a second electrode disposed on the plurality of light-emitting elements. The display device further includes a passivation layer covering the first electrode. The display device further includes a first opening hole at the passivation layer. The first opening hole extends through the passivation layer. The passivation layer has a first opening hole exposing a portion of an upper surface of the first electrode.

### CROSS-REFERENCE TO RELATED APPLICATION

This application claims priority to and the benefit of Korean Patent Application No. 10-2023-0116919, filed Sep. 4, 2023, the disclosure of which is incorporated herein by reference in its entirety.

### BACKGROUND

### Technical Field

Embodiments relate to a display device using an inorganic light emitting diode as a light source.

### Description of the Related Art

An electroluminescent display device includes an organic light emitting display device in which an organic light emitting diode (OLED) is disposed, and an inorganic light emitting display device (hereinafter referred to as “LED display device”) in which an inorganic light emitting diode (hereinafter referred to as “LED”) is disposed.

Since the electroluminescent display device displays an image using a self-luminous element, it does not require a separate light source, such as a backlight unit, and can be implemented in thin and diverse forms.

The organic light emitting display device requires a design to prevent penetration of oxygen and moisture because oxidation between an organic light emitting layer and an electrode may occur due to penetration of moisture and oxygen.

Recently, as an example of the inorganic light emitting display device, a micro LED display device in which micro LEDs are arranged in pixels has been attracting attention as a next-generation display device. The micro LED may be an inorganic LED with a size of 100 μm or less.

The micro LED is manufactured through a separate semiconductor process, and can be disposed in each sub-pixel for each color by being transferred to a pixel position on a display panel substrate of a display device.

### BRIEF SUMMARY

Before the micro LED is transferred, wires disposed on the substrate of the micro LED display device may be exposed to various manufacturing processes. In addition, it may result in problems such as chemical damage on wires caused by solutions used in the manufacturing process, short circuits caused by foreign matters generated during the manufacturing process, and decreased reflectivity due to the manufacturing process. Accordingly, various embodiments of the present disclosure provide a display device that can improve the light emission efficiency of a light-emitting element while solving one or more technical problems in the related art including the above-mentioned problem.

The present disclosure provides a display panel and a display device including the same that protect wires disposed on a substrate using a passivation layer made of an inorganic material.

The present disclosure provides a display panel and a display device including the same that improve the light emission efficiency of a light-emitting element and control the resistance of wires by presenting various stack structures for wires disposed under the light-emitting element using various types of metals.

The present disclosure provides a display panel and a display device including the same that prevent the lifting phenomenon of a passivation layer through an opening hole formed in the passivation layer covering an insulating layer made of an organic material.

The technical benefits of the present disclosure are not limited to the above-mentioned benefits, and other benefits, which are not mentioned herein, will obviously be understood by those skilled in the art from the following description.

The present disclosure provides a display device that includes an insulating layer disposed on a substrate; a plurality of first electrodes and contact electrodes disposed on the insulating layer; a plurality of light-emitting elements disposed on the plurality of first electrodes; a second electrode disposed on the plurality of light-emitting elements; and a passivation layer covering the first electrode, wherein the passivation layer has a first opening hole exposing a portion of an upper surface of the first electrode.

The present disclosure provides a display device that includes an insulating layer disposed on a substrate; a plurality of first electrodes and contact electrodes disposed on the insulating layer; a passivation layer covering the first electrode while exposing a portion of the first electrode; a plurality of light-emitting elements disposed on the plurality of first electrodes; a solder pattern disposed between the first electrode and the light-emitting element; and a second electrode disposed on the plurality of light-emitting elements, wherein the first electrode includes a first metal layer in contact with the solder pattern, a second metal layer disposed under the first metal layer, and a third metal layer disposed under the second metal layer, and wherein a light reflectivity of the second metal layer is greater than a light reflectivity of the first and third metal layers.

According to the present disclosure, it is possible to protect the wires disposed on the substrate using the passivation layer, which is a protective film made of an inorganic material. Therefore, the yield of the display device is improved, and the embodiment enables low-power driving of the production process in terms of production energy reduction.

According to the present disclosure, it is possible to prevent the lifting phenomenon of the passivation layer through the opening hole formed in the passivation layer covering the insulating layer made of an organic material.

According to the present disclosure, it is possible to improve the reflectivity of light generated from the light-emitting element by providing a material with high reflectivity and an arrangement position in a stacked structure of wires formed using various types of metals. Therefore, the wires can improve the light emission efficiency of the display device.

According to the present disclosure, it is possible to improve the light emission efficiency by the wires and also adjust the resistance of the wires by using metal materials of different materials, thicknesses, or the like.

Various useful advantages and effects of the present disclosure are not limited to the above-described contents and will be more easily understood from descriptions of the specific embodiments.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram showing a display device according to an embodiment of the present disclosure;

FIG. 2 is an enlarged view showing area A of FIG. 1;

FIG. 3 is a diagram showing a partial area of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view showing an example in which a main light-emitting element and a sub-light-emitting element are electrically connected to a pixel driving circuit;

FIG. 8 is a diagram showing a display device according to another embodiment of the present disclosure;

FIG. 9 is a cross-sectional view taken along line IV-IV′ in FIG. 8.

FIG. 10 is a diagram showing an insulating layer in a display device according to another embodiment of the present disclosure;

FIG. 11 is a cross-sectional view taken along line V-V′ in FIG. 10;

FIG. 12 is a cross-sectional view taken along line VI-VI′ in FIG. 10;

FIG. 13 is a diagram showing an optical path of a light emitting element reflected by a signal wire of a display device according to the present disclosure;

FIG. 14 is a diagram showing a first electrode of a display device according to a comparative example; and

FIG. 15 is a diagram showing the light emission efficiency of a display device according to an embodiment of the present disclosure and a display device according to a comparative example.

### DETAILED DESCRIPTION

The advantages and features of the present disclosure and methods for accomplishing the same will be more clearly understood from embodiments described below with reference to the accompanying drawings. However, the present disclosure is not limited to the following embodiments, but may be implemented in various different forms; rather, the present embodiments will make the disclosure of the present disclosure complete and allow those skilled in the art to fully comprehend the scope of the present disclosure.

Shapes, sizes, dimensions (e.g., length, width, height, thickness, radius, diameter, area, etc.), ratios, angles, numbers, and the like disclosed in the drawings for describing the embodiments of the present disclosure are exemplary, and the present disclosure is not limited to the illustrated items.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising,” “including,” “having” and “consisting of” used herein are generally intended to allow other components to be added unless the terms are used with the term “only.” References to the singular shall be construed to include the plural unless expressly stated otherwise.

In interpreting a component, it is interpreted to include an error range even if there is no separate description.

When describing a positional or interconnected relationship between two components, such as “on top of,” “above,” “below,” “next to,” “connect or couple with,” “crossing,” “intersecting,” etc., one or more other components may be interposed between them unless “immediately” or “directly” is used.

When describing a temporal contextual relationship, such as “after,” “following,” “next to” or “before,” it may not be continuous on a time scale unless “immediately” or “directly” is used.

The terms “first,” “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Hereinafter, various embodiments of the present disclosure will be described in detail with reference to the accompanying drawings.

A display device according to an embodiment of the present disclosure includes a display panel where a display area or screen on which an image is displayed is disposed, and a pixel driving circuit that drives pixels of the display panel. The display area includes a pixel area where pixels are arranged. The pixel area includes a plurality of light emitting areas. A light-emitting element is disposed in each of the light emitting areas. The pixel driving circuit may be embedded in the display panel.

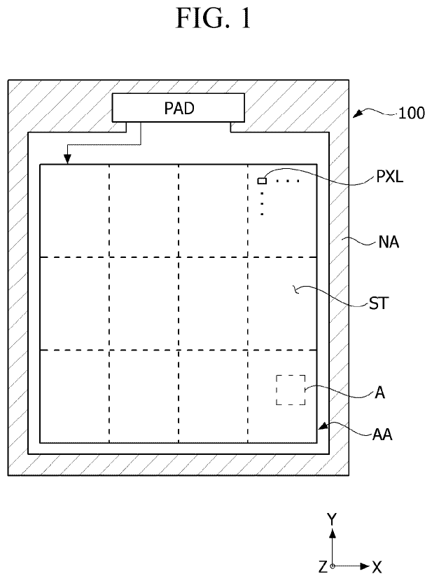

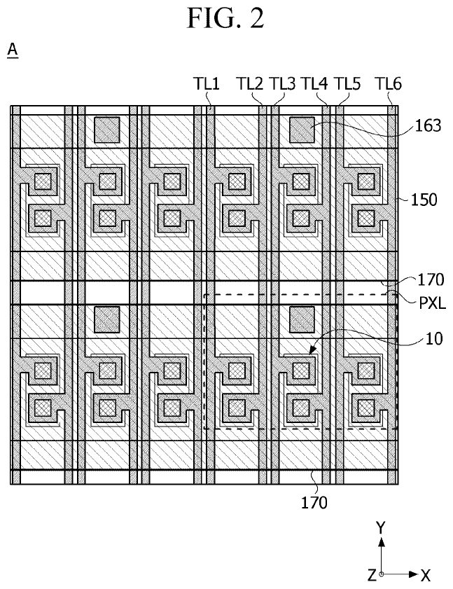

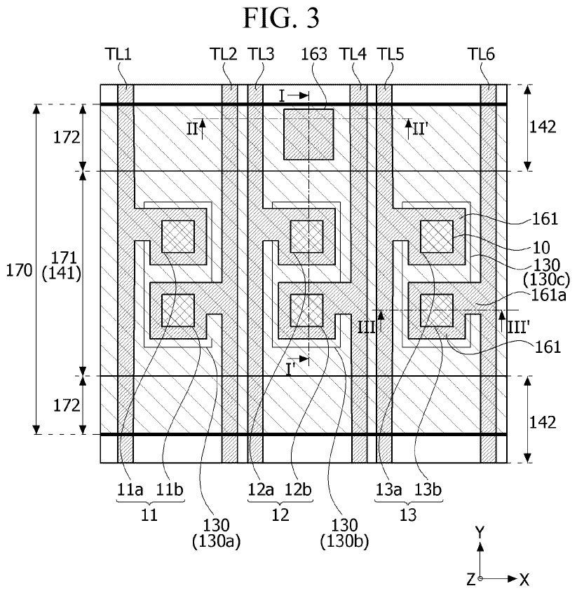

FIG. 1 is a diagram showing a display device according to an embodiment of the present disclosure. FIG. 2 is an enlarged view showing area A of FIG. 1. FIG. 3 is a diagram showing a partial area of a pixel.

Referring to FIGS. 1 and 2, the display device 100 according to an embodiment of the present disclosure includes a display panel that visually reproduces an input image. The display panel may include a display area AA where an image is displayed, and a non-display area NA where the image is not displayed. In the non-display area NA, various wires and a driving circuit may be mounted, and a pad portion PAD to which integrated circuits, printed circuits, etc., are connected may be disposed. Here, the display panel may be a panel with a rectangular structure having a width in the X-axis direction, a length in the Y-axis direction, and a thickness in the Z-axis direction. At this time, the width and length of the display panel may be set to various design values depending on the application field of the display device. In addition, the X-axis direction may refer to the width direction, row direction, or horizontal direction, the Y-axis direction may refer to the length direction, column direction, or vertical direction, and the Z-axis direction may refer to the height direction or thickness direction. Also, the X-axis direction, the Y-axis direction, and the Z-axis direction may be perpendicular to each other, but they may also refer to different directions that are not perpendicular to each other. Accordingly, each of the X-axis direction, the Y-axis direction, and the Z-axis direction may be described as any one of a first direction, a second direction, and a third direction. And, a surface extending in the X-axis direction and the Y-axis direction may refer to a horizontal surface.

A plurality of light-emitting elements 10 disposed in the display area AA and forming a pixel PXL may be micro-sized inorganic light-emitting elements. The inorganic light-emitting elements may be grown on a silicon wafer and then attached to the display panel through a transfer process.

The transfer process of the light-emitting elements 10 may be performed for each pre-divided area. Although the display area AA is divided into nine transfer areas ST in FIG. 1, the size or number of divisions of the transfer areas ST is not limited to this. The transfer process may be performed sequentially or simultaneously in the first to ninth transfer areas ST. In each transfer area ST, a blue light-emitting element 10, a green light-emitting element 10, and a red light-emitting element 10 may be sequentially transferred.

In the non-display area NA, a data driving circuit or a gate driving circuit may be disposed, and wires through which control signals for controlling these driving circuits are supplied may be disposed. Here, the control signal includes various timing signals such as a clock signal, an input data enable signal, and a synchronization signal, and it may be received through the pad portion PAD.

The pixels PXL may be driven by a pixel driving circuit. The pixel driving circuit may drive a plurality of pixels by receiving a driving voltage, an image signal (digital signal), a synchronization signal synchronized with the image signal, etc., and outputting an anode voltage and a cathode voltage of the light-emitting element 10. The driving voltage may be a high potential voltage (EVDD). The cathode voltage may be a low potential voltage (EVSS) commonly applied to the pixels. The anode voltage may be a voltage corresponding to a pixel data value of the image signal. The pixel driving circuit may be disposed in the non-display area NA or below the display area AA.

Each of the pixels PXL may include a plurality of sub-pixels having different colors. For example, the plurality of pixels may include a red sub-pixel in which the light-emitting element 10 that emits light in a red wavelength is disposed, a green sub-pixel in which the light-emitting element 10 that emits light in a green wavelength is disposed, and a blue sub-pixel in which the light-emitting element 10 that emits light in a blue wavelength is disposed. The plurality of pixels may further include white sub-pixels.

Referring to FIGS. 2 and 3, the plurality of pixels PXL may be sequentially arranged in the first direction (X-axis direction) and the second direction (Y-axis direction). In the pixel of the display area AA, a plurality of sub-pixels of the same color may be arranged. For example, each of the plurality of pixels may include a first red sub-pixel in which a first-first light-emitting element 11a that emits light in a red wavelength is disposed, a second red sub-pixel in which a first-second light-emitting element 11b that emits light in a red wavelength is disposed, a first green sub-pixel in which a second-first light-emitting element 12a that emits light in a green wavelength is disposed, a second green sub-pixel in which a second-second light-emitting element 12b that emits light in a green wavelength is disposed, a first blue sub-pixel in which a third-first light-emitting element 13a that emits light in a blue wavelength is disposed, and a second blue sub-pixel in which a third-second light-emitting element 13b that emits light in a blue wavelength is disposed. The first-first light-emitting element 11a, the second-first light-emitting element 12a, and the third-first light-emitting element 13a can be interpreted as main light-emitting elements. The first-second light-emitting element 11b, the second-second light-emitting element 12b, and the third-second light-emitting element 13b can be interpreted as sub-light-emitting elements.

One sub-pixel includes at least one light-emitting element, and if one light-emitting element becomes defective, the brightness of the sub-pixel can be adjusted by increasing the brightness of the other light-emitting elements. However, it is not necessarily limited to this, and one sub-pixel may include only one light-emitting element.

A plurality of first electrodes 161 are each disposed under the light-emitting element 10 and may be selectively connected to a plurality of signal wires TL (e.g., first to sixth signal wires TL1 to TL6 as illustrated in the figures) through a connection portion 161a. A high potential voltage may be applied to the pixel driving circuit through the first to sixth signal wires TL1 to TL6. The first to sixth signal wires TL1 to TL6 and the first electrode 161 may be formed as an integrated electrode pattern during an electrode patterning process.

Exemplarily, a first signal wire TL1 may be connected to the anode electrode of the first red sub-pixel, and a second signal wire TL2 may be connected to the anode electrode of the second red sub-pixel. A third signal wire TL3 may be connected to the anode electrode of the first green sub-pixel, and a fourth signal wire TL4 may be connected to the anode electrode of the second green sub-pixel. A fifth signal wire TL5 may be connected to the anode electrode of the first blue sub-pixel, and a sixth signal wire TL6 may be connected to the anode electrode of the second blue sub-pixel. If one sub-pixel includes only one light-emitting element, the number of signal wires TL may be reduced by half.

A second electrode 170 may be a cathode electrode that is disposed in each row and applies a cathode voltage to the light-emitting elements 10 continuously arranged in the first direction (X-axis direction). The plurality of second electrodes 170 may be arranged to be spaced apart from each other in the second direction (Y-axis direction). The plurality of second electrodes 170 may be connected to the cathode voltage through a contact electrode 163. Each of the plurality of second electrodes 170 may be electrically connected to the contact electrode 163. However, it is not necessarily limited to this, and the second electrode 170 may not be divided into plural pieces but may be composed of one electrode layer to function as a common electrode.

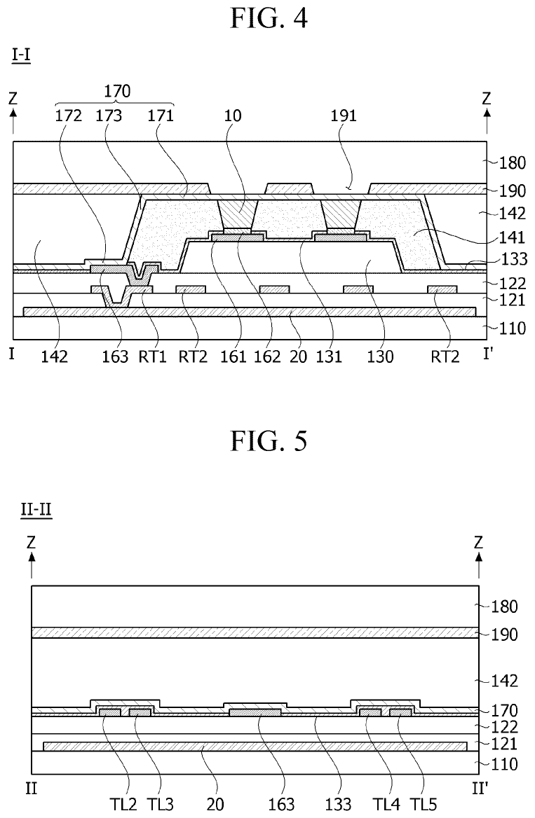

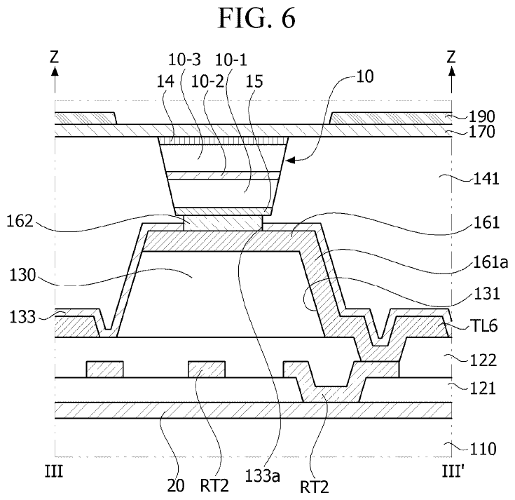

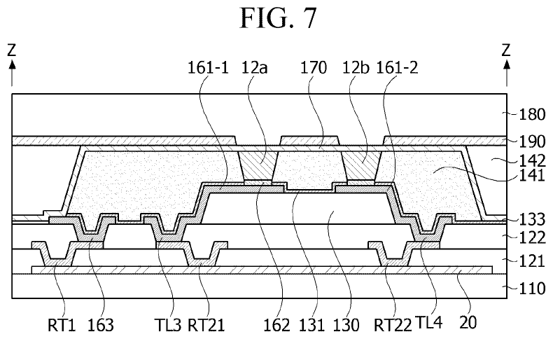

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′ in FIG. 3. FIG. 7 is a cross-sectional view showing an example in which two light-emitting elements are electrically connected to a pixel driving circuit.

Referring to FIGS. 3 to 5, the display device according to an embodiment includes a plurality of first electrodes 161 and contact electrodes 163 disposed on a substrate 110, a plurality of light-emitting elements 10 disposed on the plurality of first electrodes 161, a first optical layer 141 disposed between the plurality of light-emitting elements 10, and a second electrode 170 disposed on the plurality of light-emitting elements 10.

The substrate 110 may be made of plastic with flexibility. For example, the substrate 110 may be manufactured as a single-layer or multi-layer substrate of a material selected from, but is not limited to, polyimide, polyethylene terephthalate, polyethylene naphthalate, polycarbonate, polyethersulfone, polyarylate, polysulfone, and cyclic-olefin copolymer. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes a plurality of thin film transistors, it may be formed on the substrate 110 through a thin film transistor (TFT) manufacturing process. In an embodiment, the pixel driving circuit 20 may be a general term for the plurality of thin film transistors electrically connected to the light-emitting element 10.

The pixel driving circuit 20 may be a driving driver manufactured on a single crystal semiconductor substrate 110 using a metal-oxide-silicon field effect transistor (MOSFET) manufacturing process. The driving driver may include a plurality of pixel driving circuits to drive a plurality of sub-pixels. When the pixel driving circuit 20 is implemented as the driving driver, after an adhesive layer is disposed on the substrate 110, the driving driver may be mounted on the adhesive layer through a transfer process.

A buffer layer 121 may be disposed on the substrate 110 to cover the pixel driving circuit 20. The buffer layer 121 may be made of an organic insulating material, which is for example, but is not limited to, photosensitive photo acryl or photosensitive polyimide.

The buffer layer 121 may use an inorganic insulating material, for example, silicon nitride (SiNx) or silicon oxide (SiO₂), stacked in a multi-layer manner, or use an organic insulating material and an inorganic insulating material stacked in a multi-layer manner.

An insulating layer 122 may be disposed on the buffer layer 121. The insulating layer 122 may be made of an organic insulating material, which is for example, but is not limited to, photosensitive photo acryl or photosensitive polyimide. Connection wires (e.g., first and second connection wires RT1 and RT2 as illustrated in the figures) may be disposed on the buffer layer 121. The first and second connection wires RT1 and RT2 may be connected to the corresponding first to sixth signal wires TL1 to TL6. The first and second connection wires RT1 and RT2 may include a plurality of wire patterns arranged on different layers with one or more insulating layers interposed therebetween. The wire patterns arranged on different layers may be electrically connected through a contact hole penetrating the insulating layer.

A plurality of bank patterns 130 may be disposed on the insulating layer 122. At least one light-emitting element 10 may be disposed on each bank pattern 130. For example, a first light-emitting element 11 may be disposed on a first bank pattern 130a, a second light-emitting element 12 may be disposed on a second bank pattern 130b, and a third light-emitting element 13 may be disposed on a third bank pattern 130c.

The bank pattern 130 may be made of an organic insulating material, which is for example, but is not limited to, photosensitive photo acryl or photosensitive polyimide. The bank pattern 130 may define the location where the light-emitting element 10 will be attached during the transfer process of the light-emitting element 10. The bank pattern 130 may be omitted.

A solder pattern 162 may be disposed on the first electrode 161. The solder pattern 162 may be made of, but is not limited to, indium (In), tin (Sn), or an alloy thereof.

The plurality of light-emitting elements 10 may each be mounted on the solder pattern 162. One pixel may include the light-emitting elements 10 of three colors. The first light-emitting element 11 may be a red light-emitting element, the second light-emitting element 12 may be a green light-emitting element, and the third light-emitting element 13 may be a blue light-emitting element. Two light emitting elements may be mounted in each sub-pixel.

The first optical layer 141 may cover the plurality of light-emitting elements 10 and the bank pattern 130. Therefore, the first optical layer 141 may be disposed between the plurality of light-emitting elements 10 and between the plurality of bank patterns 130. The first optical layer 141 extends in the first direction (X) and is arranged to be spaced apart in the second direction (Y) to separate pixels arranged to be spaced apart in the second direction. Accordingly, the first optical layer 141 may be separated between pixel rows. Here, the row may refer to the first direction. Additionally, one pixel row consisting of a plurality of pixels arranged along the first direction may be called a pixel group. Therefore, the display panel may include a plurality of pixel groups arranged to be spaced apart from each other in the second direction. For example, because the first optical layer 141 arranged along the first direction is disposed around the pixels, and the plurality of first optical layers 141 disposed corresponding to the plurality of pixel groups are spaced apart from each other in the second direction, one first optical layer 141 disposed around the pixels forming one row may be separated from the other first optical layer 141 disposed around the pixels forming another row.

The first optical layer 141 may include an organic insulating material in which fine metal particles such as titanium dioxide particles are dispersed. Light emitted from the plurality of light-emitting elements 10 may be scattered by fine metal particles dispersed in the first optical layer 141 and emitted to the outside.

The second electrode 170 may be disposed on the plurality of light-emitting elements 10. The second electrode 170 may be commonly connected to the plurality of pixels PXL. The second electrode 170 may be a thin electrode that transmits light. The second electrode 170 may be a transparent electrode material, which is for example, but is not limited to, indium tin oxide (ITO).

The second electrode 170 may extend in the first direction (X-axis direction) and be spaced apart in the second direction (Y-axis direction). For example, one second electrode 170 may be formed to extend in the first direction, and a plurality of second electrodes 170 extending in the first direction may be arranged to be spaced apart from each other along the second direction. At this time, the second electrode 170 may be arranged to correspond to each of the pixels arranged to be spaced apart from each other in the second direction. The second electrode 170 may include a first region 171 disposed on the upper surface of the light-emitting element 10 and the upper surface of the first optical layer 141, a second region 172 being in contact with and electrically connected to the contact electrode 163, and a third region 173 disposed on the side of the first optical layer 141 and connecting the first region 171 and the second region 172.

In a plan view, the plurality of second electrodes 170 may each overlap with the first optical layer 141, and the third region 173 may cover the outer plane of the first optical layer 141.

A second optical layer 142 may be an organic insulating material surrounding the first optical layer 141. The second optical layer 142 may be disposed on the insulating layer 122 together with the first optical layer 141. The first optical layer 141 and the second optical layer 142 may include the same material (e.g., siloxane). For example, the first optical layer 141 may be siloxane that contains titanium oxide (TiOₓ), and the second optical layer 142 may be siloxane that does not contain titanium oxide (TiOₓ). However, it is not necessarily limited to this, and the first optical layer 141 and the second optical layer 142 may be formed of the same material or may be formed of different materials.

According to an embodiment, the second region 172 of the second electrode 170 is connected to the contact electrode 163 in an overall flat state, so excessive stress is not concentrated at the connection point with the contact electrode 163. Therefore, cracks can be effectively prevented from occurring in the second electrode 170.

The second optical layer 142 may cover the second and third regions 172 and 173 of the second electrode 170. The upper surface of the second optical layer 142 and the upper surface of the first region 171 of the second electrode 170 may be coplanar. That is, the first region 171 and the second optical layer 142 may function as a planarization layer. Due to this, there is no step on the surface where a black matrix 190 is formed, so a pattern of the black matrix 190 can be easily formed on the first optical layer 141 and the second optical layer 142. However, it is not necessarily limited to this, and the upper surfaces of the second optical layer 142 and the second electrode 170 may have different heights.

The black matrix 190 may be an organic insulating material to which black pigment is added. The second electrode 170 may be in contact with the contact electrode 163 under the black matrix 190. A transmission hole 191 through which light emitted from the light-emitting element 10 is output to the outside may be formed between the patterns of the black matrix 190. The transmission hole 191 may overlap with the light-emitting element 10 in the Z-axis direction, and a partial area of the black matrix 190 may overlap with the first optical layer 141 in the Z-axis direction. Here, the Z-axis direction may be called the third direction. Therefore, the black matrix 190 can solve the problem in which light emitted from each of neighboring light-emitting elements 10 is mixed by the first optical layer 141 and then emitted.

A cover layer 180 may be an organic insulating material that covers the black matrix 190 and the second electrode 170. In FIGS. 2 and 3, the black matrix 190 and the cover layer 180 are not shown.

The contact electrode 163 may be electrically connected to the first connection wire RT1 disposed thereunder, and the first connection wire RT1 may be connected to the pixel driving circuit 20. Therefore, the cathode voltage may be applied to the second electrode 170 through the contact electrode 163. The first electrode 161 may be electrically connected to the second connection wire RT2. This will be described later.

Referring to FIG. 5, the contact electrode 163 and first to sixth signal wires TL1 to TL6 may be disposed on the same plane. The pixel driving circuit 20 may be disposed under the contact electrode 163 and the first to sixth signal wires TL1 to TL6. When the pixel driving circuit 20 is a driving driver, a plurality of driving drivers may be disposed within the display panel.

A passivation layer 133 may expose the contact electrode 163 so that the contact electrode 163 and the second electrode 170 are electrically connected. In addition, the passivation layer 133 may insulate the first to sixth signal wires TL1 to TL6 and the second electrode 170. Here, the passivation layer 133 may be formed of an inorganic material.

Referring to FIG. 6, the connection portion 161a of the first electrode 161 may extend to one side 131 of the bank pattern 130 and be electrically connected to the second connection wire RT2 disposed on the buffer layer 121.

The first electrode 161, the connection portion 161a, the signal wires TL, and/or the first and second connection wires RT1 and RT2 may include a single or multi-layer metal layer selected from titanium (Ti), molybdenum (Mo), and aluminum (Al).

The passivation layer 133 is disposed on the first electrode 161 and the signal wires TL and may have an opening hole 133a exposing the solder pattern 162. Here, the opening hole 133a exposing the solder pattern 162 may be referred to as a first opening hole 133a. The first opening hole 133a may extend through the passivation layer 133 such that it exposes an upper surface of the underlying layer. Here, the first electrode 161 is disposed beneath the first opening hole 133a. Accordingly, the first opening hole 133a may expose an upper surface of the first electrode 161 that is not covered by the passivation layer 133. In some embodiments, the solder pattern 162 is disposed at the location of the first opening hole 133a.

The light-emitting element 10 may include a first conductive semiconductor layer 10-1, an active layer 10-2 disposed on the first conductive semiconductor layer 10-1, and a second conductive semiconductor layer 10-3 disposed on the active layer 10-2. A first driving electrode 15 may be disposed under the first conductive semiconductor layer 10-1, and a second driving electrode 14 may be disposed on the second conductive semiconductor layer 10-3.

The light-emitting element 10 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductive semiconductor layer 10-1 may be implemented with compound semiconductor such as group III-V or group II-VI and doped with a first dopant. The first conductive semiconductor layer 10-1 may be formed of, but is not limited to, one or more of a semiconductor material with a composition formula of Alₓ₁In_{y1}Ga_{(1-x1-y1)}N (0≤x1≤1, 0≤y1≤1, 0≤x1+y1≤1), or a material selected from InAlGaN, AlGaAs, GaP, GaAs, GaAsP, or AlGaInP. When the first dopant is an n-type dopant such as Si, Ge, Sn, Se, or Te, the first conductive semiconductor layer 10-1 may be an n-type nitride semiconductor layer. However, when the first dopant is a p-type dopant, the first conductive semiconductor layer 10-1 may be a p-type nitride semiconductor layer.

The active layer 10-2 is a layer where electrons (or holes) injected through the first conductive semiconductor layer 10-1 and holes (or electrons) injected through the second conductive semiconductor layer 10-3 meet. The active layer 10-2 transitions to a low energy level as electrons and holes recombine, thus generating light with a corresponding wavelength.

The active layer 10-2 may have any one of a single well structure, a multi-well structure, a single quantum well structure, a multi quantum well (MQW) structure, a quantum dot structure, or a quantum wire structure, but the structure of the active layer 10-2 is not limited to this. The active layer 10-2 can generate light in the visible light wavelength range. By way of example, the active layer 10-2 may output light in any one of blue, green, and red wavelength bands.

The second conductive semiconductor layer 10-3 may be disposed on the active layer 10-2. The second conductive semiconductor layer 10-3 may be implemented with a compound semiconductor such as group III-V or group II-VI and doped with a second dopant. The second conductive semiconductor layer 10-3 may be formed of a semiconductor material with a composition formula of Inₓ₂Al_{y2}Ga_{1-x2-y2}N (0≤x2≤1, 0≤y2≤1, 0≤x2+y2≤1) or a material selected from AlInN, AlGaAs, GaP, GaAs, GaAsP, or AlGaInP. When the second dopant is a p-type dopant such as Mg, Zn, Ca, Sr, or Ba, the second conductive semiconductor layer 10-3 doped with the second dopant may be a p-type semiconductor layer. When the second dopant is an n-type dopant, the second conductive semiconductor layer 10-3 may be an n-type nitride semiconductor layer.

Although the embodiment describes a vertical structure in which the driving electrodes 14 and 15 are disposed on and under the light emitting structure, the light-emitting element may have a lateral structure or a flip chip structure rather than the vertical structure.

Referring to FIG. 7, a main light-emitting element 12a and a sub-light-emitting element 12b of the sub-pixel may be disposed on the bank pattern 130. The second light-emitting element 12 will be described by way of example. A first-first electrode 161-1 connected to the main light-emitting element 12a may extend to one side of the bank pattern 130 and be electrically connected to a second-first connection wire RT21 disposed thereunder. A first-second electrode 161-2 connected to the sub-light-emitting element 12b may extend to the other side of the bank pattern 130 and be electrically connected to a second-second connection wire RT22 disposed thereunder.

The pixel driving circuit 20 may apply an anode voltage to the main light-emitting element 12a through the second-first connection wire RT21, and apply an anode voltage to the sub-light-emitting element 12b through the second-second connection wire RT22. The pixel driving circuit 20 may apply a cathode voltage to the main light-emitting element 12a and the sub-light-emitting element 12b through the first connection wire RT1 and the second electrode 170.

The pixel driving circuit 20 may adjust luminance by driving only the main light-emitting element 12a or by simultaneously driving the main light-emitting element 12a and the sub-light-emitting element 12b. If the main light emitting element 12a is darkened, the luminance may be adjusted by driving only the sub-light-emitting element 12b.

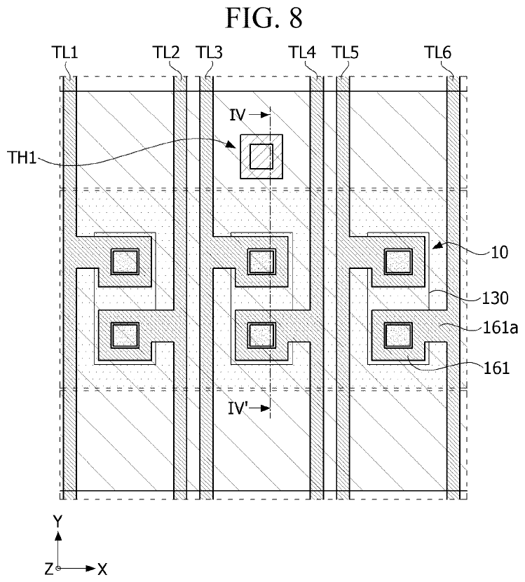

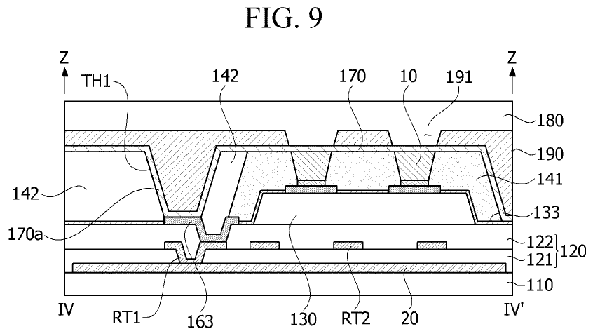

FIG. 8 is a diagram showing a display device according to another embodiment of the present disclosure. FIG. 9 is a cross-sectional view taken along line IV-IV′ in FIG. 8.

Referring to FIGS. 8 and 9, the second electrode 170 may be electrically connected to the contact electrode 163 through a contact hole TH1 formed in the second optical layer 142. The second optical layer 142 may have the contact hole TH1 exposing the contact electrode 163. The second electrode 170 inserted into the contact hole TH1 of the second optical layer 142 may be in contact with the upper surface of the contact electrode 163. The contact hole TH1 may be formed in an outer area of the pixel.

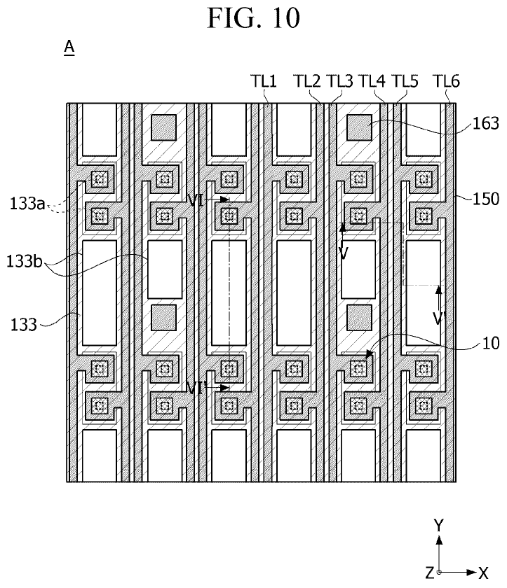

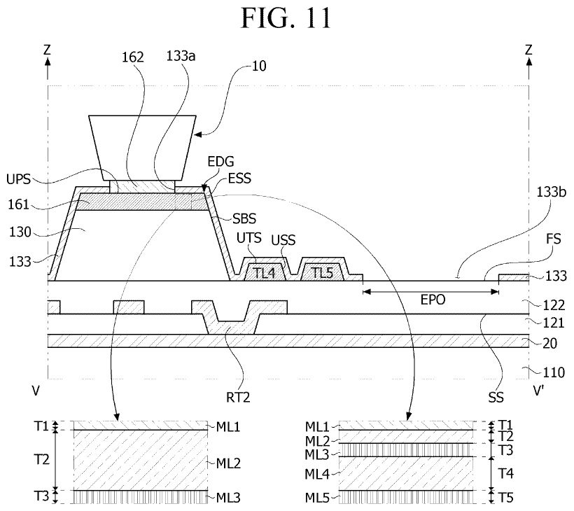

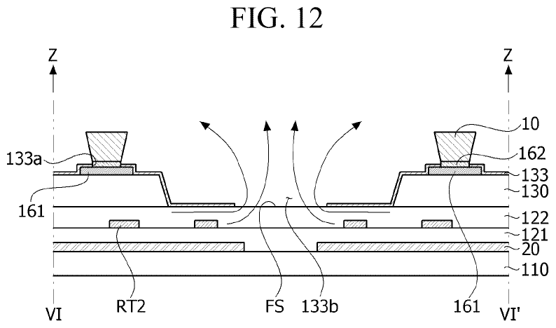

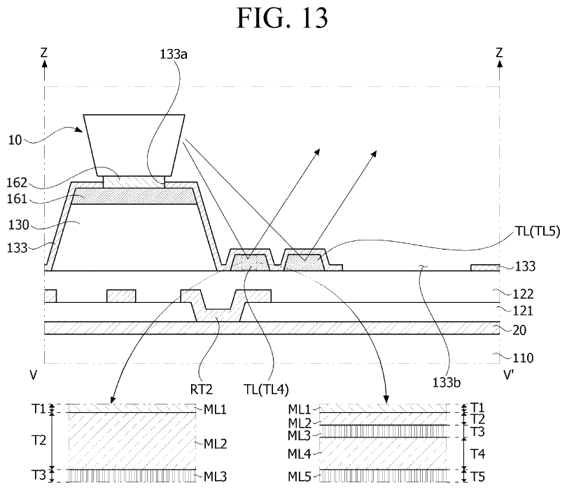

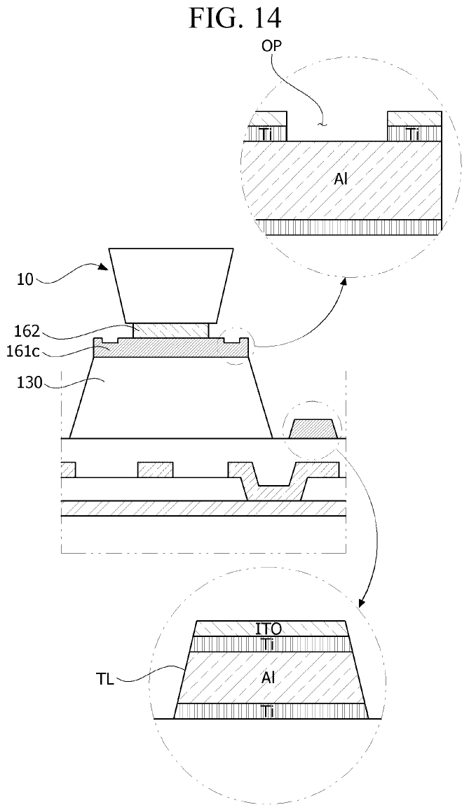

FIG. 10 is a diagram showing an insulating layer in a display device according to another embodiment of the present disclosure. FIG. 11 is a cross-sectional view taken along line V-V′ in FIG. 10. FIG. 12 is a cross-sectional view taken along line VI-VI′ in FIG. 10. FIG. 13 is a diagram showing an optical path of a light-emitting element reflected by a signal wire according to the present disclosure. FIG. 14 is a diagram showing a first electrode of a display device according to a comparative example. The arrow shown in FIG. 12 may indicate an exhaust path of gas generated from the insulating layer 122, and the arrow shown in FIG. 13 may indicate an optical path of light generated from the light-emitting element.

Referring to FIGS. 4 and 10, the display device according to the present disclosure may include a substrate 110, a pixel driving circuit 20 disposed on the substrate 110, a buffer layer 121 disposed on the substrate 110 and covering the pixel driving circuit, first and second connection wires RT1 and RT2 disposed on the buffer layer 121, an insulating layer 122 disposed on the buffer layer 121 to cover the first and second connection wires RT1 and RT2, a contact electrode 163, a bank pattern 130 and the signal wires TL disposed on the insulating layer 122, a first electrode 161 disposed on the bank pattern 130, a solder pattern 162 disposed on the first electrode 161, a passivation layer 133 having a first opening hole 133a and a second opening hole 133b and covering the bank pattern 130, the signal wires TL and the first electrode 161, a light-emitting element 10 disposed on the solder pattern 162, and a second electrode 170 disposed on the light-emitting element 10. In addition, the display device according to the present disclosure may include a first optical layer 141 disposed around the light-emitting element 10, and a second optical layer 142 disposed around the first optical layer 141. Additionally, the display device according to the present disclosure may include a black matrix 190 formed on the second optical layer 142, and a cover layer 180 disposed on the black matrix 190.

When comparing the display device according to the comparative example and the display device according to the present disclosure with reference to FIGS. 11 and 14, the display device according to the comparative example differs from the display device according to the present disclosure in that the display device according to the comparative example doesn't have the passivation layer 133 of the display device according to the present disclosure, a second layer containing titanium (Ti) is disposed under a first layer of the first electrode 161c in contact with the solder pattern 162, an opening OP for reflection is formed in the first electrode 161c to expose a third layer disposed under the second layer and containing aluminum (Al), and the first electrode 161c is formed of four metal layers. Here, a fourth layer disposed under the third layer is made of the same material as the second layer. That is, the first electrode 161c of the display device according to the comparative example and the first electrode 161 of the display device according to the present disclosure are different in shape and structure, and the display device according to the present disclosure is different from the display device according to the comparative example in that it further includes a passivation layer 133.

As shown in FIG. 14, in the case of the comparative example having no passivation layer surrounding the first electrode 161c or the signal wire TL, the first electrode 161c, the signal wire TL, and the like may be exposed to solutions used in the subsequent processes for manufacturing the display device, thereby being corroded or damaged. For example, aluminum forming the first electrode 161c or the signal wire TL may be easily corroded by exposure to a developer. Additionally, short circuit defects may occur in the signal wires TL arranged adjacent to each other due to foreign substances such as metal flakes generated in the subsequent processes.

Therefore, the display device according to the present disclosure can prevent damage to the first electrode 161 or the signal wires TL by using the passivation layer 133 and also prevent in advance short circuits that may occur between wires. Accordingly, the display device according to the present disclosure can improve production yield by using the passivation layer 133, thereby enabling high efficiency in terms of reducing production energy.

The passivation layer 133 may be made of an inorganic insulating material. For example, the passivation layer 133 may be formed as a single layer or multilayer using silicon nitride (SiNₓ) or silicon oxide (SiO₂).

The passivation layer 133 may be formed through an etch back process to cover the first electrode 161 and the signal wires TL after forming the first electrode 161 and the signal wires TL.

Referring to FIGS. 10 to 12, the passivation layer 133 may have a first opening hole 133a exposing a portion of the upper surface of the first electrode 161, and a second opening hole 133b exposing a portion of the insulating layer 122.

The first opening hole 133a may expose the upper surface of the first electrode 161. At this time, ratio of the horizontal area of the first electrode 161 to the horizontal area of the first opening hole 133a may be 8:1 to 10:1. For example, the horizontal area of the first electrode 161 may be 8 to 10 times the horizontal area of the first opening hole 133a.

In the first opening hole 133a, a solder pattern 162 may be disposed to be in contact with the first electrode 161.

As the first opening hole 133a is formed in the passivation layer 133, a portion of the passivation layer 133 may cover an edge of the upper surface of the first electrode 161. Therefore, a portion of the passivation layer 133 may overlap with the first electrode 161 in the Z-axis direction, but it is not necessarily limited thereto. For example, in order to improve the light emission efficiency of the light-emitting element 10, the passivation layer 133 may be disposed so that the entire upper surface of the first electrode 161 is exposed.

Because the passivation layer 133 is formed of an inorganic insulating material different from the insulating layer 122 and covers almost the entire area of the insulating layer 122 except for the first opening hole 133a of the passivation layer 133, there is difficulty in discharging gas generated from the insulating layer 122 during the subsequent processes. In addition, the gas generated from the insulating layer 122 may cause the passivation layer 133 to be lifted.

Accordingly, the display device according to the present disclosure can prevent the lifting phenomenon of the passivation layer 133 by using the second opening hole 133b formed together with the first opening hole 133a. As shown in FIG. 12, the gas generated in the insulating layer 122 can be discharged through the second opening hole 133b, so that the lifting phenomenon of the passivation layer 133 can be prevented.

The second opening hole 133b may expose a portion of the insulating layer 122 and be disposed between a plurality of bank patterns 130 protruding from the upper surface of the insulating layer 122.

Considering that the signal wires TL are disposed between the bank patterns 130 in the first direction, the second opening hole 133b may be disposed between the plurality of bank patterns 130 in the second direction. Therefore, the design freedom of the second opening hole 133b can be secured. For example, because the amount of gas generated from the insulating layer 122 is different depending on the material of the insulating layer 122, the conditions of the subsequent process, etc., the design freedom can be secured through the second opening hole 133b disposed between the plurality of bank patterns 130. At this time, the insulating layer 122 may be in contact with the second optical layer 142 made of an organic material.

Ratio of the horizontal area of the insulating layer 122 to the entire horizontal area of the second opening hole 133b may be formed within a range of 4:1 to 5:1. That is, the horizontal area of the insulating layer 122 may be 4 to 5 times the entire area of the second opening hole 133b. Accordingly, the display device according to the present disclosure can prevent damage to the first electrode 161 or the signal wires TL by using the passivation layer 133, also prevent the lifting phenomenon of the passivation layer 133 through the second opening hole 133b.

The display device can improve the light emission efficiency by disposing separate reflectors on the side and bottom of the light-emitting element 10. However, disposing the reflectors require a separate process, so the production cost may increase.

The display device according to the present disclosure can improve the light emission efficiency and also adjust the resistance of the first electrode 161 or the signal wires TL by providing various metal stack structures to the first electrode 161 or the signal wires TL using metal materials of different materials, thicknesses, or the like. Additionally, the display device according to the present disclosure can improve the productivity because of having a separate reflector.

Referring to FIGS. 11 and 13, the first electrode 161 and the signal wires TL may be formed to have a metal stacked structure in which multiple metal layers are formed using metal materials of different materials, thicknesses, or the like. Likewise, for the embodiment as shown in FIG. 6, the first electrode 161, the connection portion 161a, and the signal wires TL may be formed simultaneously through the same manufacturing process. Here, the thickness may refer to the width between one surface and the other surface of a metal layer disposed in the Z-axis direction.

The first electrode 161 may include a first metal layer ML1 disposed under the solder pattern 162, a second metal layer ML2 disposed under the first metal layer ML1, and a third metal layer ML3 disposed under the second metal layer ML2. When the first electrode 161 is composed of the first metal layer ML1, the second metal layer ML2, and the third metal layer ML3, the first electrode 161 may be formed by deposition in the order of the third metal layer ML3, the second metal layer ML2, and the first metal layer ML1, followed by patterning through a photolithography process and an etching process.

In addition, the first electrode 161 may further include a fourth metal layer ML4 disposed under the third metal layer ML3, and a fifth metal layer ML5 disposed under the fourth metal layer ML4. When the first electrode 161 is composed of the first metal layer ML1, the second metal layer ML2, the third metal layer ML3, the fourth metal layer ML4, and the fifth metal layer ML5, the first electrode 161 may be formed by deposition in the order of the fifth metal layer ML5, the fourth metal layer ML4, the third metal layer ML3, the second metal layer ML2, and the first metal layer ML1, followed by patterning through a photolithography process and an etching process.

The first metal layer ML1 may be disposed in contact with the lower portion of the solder pattern 162 and electrically connected to the solder pattern 162.

Additionally, the first metal layer ML1 may include a transparent conductive oxide layer such as indium tin oxide (ITO) or indium zinc oxide (IZO), which has good adhesion and corrosion and acid resistance. Here, the first metal layer ML1 may be called an adhesive layer.

Additionally, the first metal layer ML1 may be formed to have a first thickness T1. The first thickness T1 may be adjusted.

The second metal layer ML2 may be formed of a material with higher light reflectivity than the first metal layer ML1. At this time, the second metal layer ML2 may be formed of a material with higher light reflectivity than the third metal layer ML3. For example, the second metal layer ML2 may include aluminum (Al) or silver (Ag).

That is, the light reflectivity of the second metal layer ML2 may be greater than that of the first and third metal layers ML1 and ML3. Accordingly, among the light generated by the light-emitting element 10, the light passing through the first metal layer ML1 is reflected by the second metal layer ML2, so the second metal layer ML2 of the first electrode 161 can improve the light emission efficiency of the display device. When the passivation layer 133 covers a portion of the upper surface of the first electrode 161, the light emission efficiency of the display device according to the present disclosure may be somewhat reduced. Accordingly, disposing the passivation layer 133 to expose the entire upper surface of the first electrode 161 can further improve the light emission efficiency of the display device according to the present disclosure.

In the comparative example, only a portion of the third layer containing aluminum (Al) is exposed through the reflection opening OP, and the second layer contains titanium (Ti), which has lower reflectivity than the third layer, so the first electrode 161c of the comparative example has a relatively lower light reflectivity than the first electrode 161 according to the present disclosure, which reflects light through the second metal layer ML2. Accordingly, the display device according to the present disclosure can improve the light emission efficiency of the display device by securing the area of the second metal layer ML2 for reflecting the light passing through the first metal layer ML1 with a high reflectivity. In addition, the display device according to the present disclosure can eliminate the manufacturing process for forming the opening OP of the comparative example, thus improving productivity through simplification of the manufacturing process and also reducing the defect rate due to forming the opening OP of the comparative example.

Additionally, the second metal layer ML2 may be formed to have a second thickness T2. The second thickness T2 may be adjusted.

The third metal layer ML3 may be formed of a material that has a different resistance value from the first and second metal layers ML1 and ML2. At this time, the third metal layer ML3 may be formed of a material that has a lower light reflectivity but a higher resistance value than the second metal layer ML2. For example, the third metal layer ML3 may include titanium (Ti) or molybdenum (Mo).

Additionally, the third metal layer ML3 may be formed to have a third thickness T3. The third thickness T3 may be adjusted. When the first electrode 161 includes the third metal layer ML3 and the second metal layer ML2, the second thickness T2 of the second metal layer ML2 may be greater than the third thickness T3 of the third metal layer ML3.

The fourth metal layer ML4 may be formed of the same material as the second metal layer ML2. For example, the fourth metal layer ML4 may include aluminum (Al) or silver (Ag). Here, the fourth metal layer ML4 may be formed of a material different from the second metal layer ML2 in consideration of the overall thickness and resistance of the first electrode 161, but it may be formed of the same material as the second metal layer ML2 in consideration of productivity during the manufacturing process.

Additionally, the fourth metal layer ML4 may be formed to have a fourth thickness T4. The fourth thickness T4 may be adjusted. When the first electrode 161 includes the second metal layer ML2 and the fourth metal layer ML4, the fourth thickness T4 of the fourth metal layer ML4 may be greater than the second thickness T2 of the second metal layer ML2. The second metal layer ML2 is disposed to reflect light emitted from the light-emitting element 10, but the fourth metal layer ML4 is used to adjust the resistance of the first electrode 161. Thus, the thickness of the fourth metal layer ML4 may be greater than the thickness of the second metal layer ML2. For example, ratio of the fourth thickness T4 of the fourth metal layer ML4 to the second thickness T2 of the second metal layer ML2 may be within a range of 1:1 to 5:1. That is, the thickness of the fourth metal layer ML4 may be 1 to 5 times the thickness of the second metal layer ML2.

The fifth metal layer ML5 may be formed of the same material as the third metal layer ML3. For example, the fifth metal layer ML5 may include titanium (Ti) or molybdenum (Mo).

Additionally, the fifth metal layer ML5 may be formed to have a fifth thickness T5. The fifth thickness T5 may be adjusted. In addition, the fifth thickness T5 of the fifth metal layer ML5 may be equal to the third thickness T3 of the third metal layer ML3 in consideration of productivity during the manufacturing process. Accordingly, the display device according to the present disclosure can adjust the resistance of the first electrode 161 by adjusting the third thickness T3 of the third metal layer ML3 and the fifth thickness T5 of the fifth metal layer ML5.

As shown in FIG. 11, the bank pattern 130 overlaps the light-emitting element 10 from a plan view. The first electrode 161 is between the light-emitting element 10 and the bank pattern 130. The first electrode 161 has an upper surface UPS and a side surface ESS that extends from the upper surface UPS. The portion where the upper surface UPS of the first electrode 161 and the side surface ESS of the first electrode 161 intersect with each other may be referred to as an edge portion EDG. In one embodiment, the passivation layer 133 extends from the solder pattern 162 towards the fourth signal wire TL4 and the fifth signal wire TL5. Here, the passivation layer 133 covers the upper surface UPS of the first electrode 161 and the side surface ESS of the first electrode 161. The passivation layer 133 covers a side surface SBS of the bank pattern 130, side surfaces USS of the fourth signal wire TL4, and upper surface UTS of the fourth signal wire TL4. As shown, the passivation layer 133 also covers the upper and side surfaces of the fifth signal wire TL5.

The insulating layer 122 is on the substrate 110. The insulating layer has a first surface FS and a second surface SS opposite the first surface FS. Here, the second surface SS faces the substrate 110 such that the second surface SS is closer to the substrate 110 than the first surface FS. At a portion EPO of the first surface FS of the insulating layer 122, there is an exposed portion EPO that is not covered by the passivation layer 133. The exposed portion EPO corresponds to the second hole 133b and therefore, when seen from a plan view, the exposed portion EPO at the first surface FS of the insulator 122 overlaps with the second hole 133b.

Referring to FIG. 11, at least one signal wire (e.g., TL4, TL5) is adjacent to the bank pattern 130. Here, the at least one signal wire is disposed on and contacts the insulating layer 122.

In some embodiments, the passivation layer 133 continuously and contiguously extends from an upper surface UPS of the first electrode 161 to the first surface FS of the insulating layer 122. For example, the passivation layer 133 continuously and contiguously extends between the first opening hole 133a and the second opening hole 133b. In some embodiments, the passivation layer 133 contacts the side surface of the solder pattern 162.

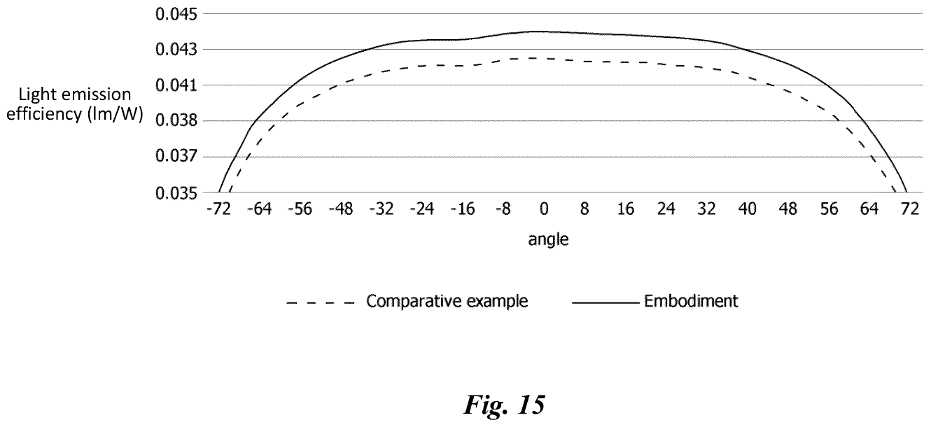

FIG. 15 is a diagram showing the light emission efficiency of a display device according to an embodiment of the present disclosure and a display device according to a comparative example.

Referring to FIG. 15, unlike the comparative example, the display device according to the embodiment of the present disclosure includes the second metal layer ML2 with a high reflectivity disposed under the transparent first metal layer ML1, and secures the area of the second metal layer ML2 that reflects light emitted from the light-emitting element 10, thereby improving the light emission efficiency to about 3.53% higher than that of the comparative example. Here, in the comparative example, in addition to the third layer containing aluminum (Al), the second layer containing titanium (Ti), which has a lower light reflectivity than the third layer, reflects the light emitted from the light-emitting element 10, so the light emission efficiency is lower than that of the display device according to the present disclosure.

In addition, the first electrode 161 may implement various stacked structures using metal layers of different materials, thicknesses, numbers, etc., thereby allowing the resistance of the first electrode 161 to be adjusted.

For example, when the first electrode 161 is composed of the first metal layer ML1, the second metal layer ML2, and the third metal layer ML3, these three metal layers ML1, ML2, and ML3 may be formed of different materials and the second thickness T2 of the second metal layer ML2 may be formed to be greater than the third thickness T3 of the third metal layer ML3. This makes it possible to secure the light emission efficiency of the display device according to the present disclosure and also adjust the resistance of the first electrode 161. At this time, considering the thickness, resistance, etc., of the first electrode 161 required for the design of the display device, the second thickness T2 of the second metal layer ML2 and the third thickness T3 of the third metal layer ML3 may be adjusted. As shown in FIG. 11, the second thickness T2 of the second metal layer ML2 may be greater than the third thickness T3 of the third metal layer ML3.

In addition to the first to third metal layers ML1 to ML3, a metal layer may be added to the first electrode 161. For example, when the first electrode 161 is composed of the first metal layer ML1, the second metal layer ML2, the third metal layer ML3, the fourth metal layer ML4, and the fifth metal layer ML5, the second metal layer ML2 and the fourth metal layer ML4 may be formed of the same material, and the third metal layer ML3 and the fifth metal layer ML5 may be formed of the same material. At this time, considering the thickness, resistance, etc., of the first electrode 161 required for the design of the display device, the second thickness T2 of the second metal layer ML2 may be smaller than the fourth thickness T4 of the fourth metal layer ML4 and may be smaller than or equal to the third thickness T3 of the third metal layer ML3. Additionally, the third thickness T3 of the third metal layer ML3 may be equal to the fifth thickness T5 of the fifth metal layer ML5. Also, the fourth thickness T4 of the fourth metal layer ML4 may be greater than the third thickness T3 of the third metal layer ML3.

The display device according to the present disclosure can further improve the light emission efficiency of the display device by forming the signal wires TL simultaneously with the first electrode 161 to have the same stacked structure as the first electrode 161.

The signal wires TL may each be connected to the first electrode 161 through the connection portion 161a and disposed adjacent to the light-emitting element 10. In addition, in the display device according to the present disclosure, the second metal layer ML2 with a high light reflectivity may be disposed under the transparent first metal layer ML1 of the signal wires TL, so that the second metal layer ML2 may reflect light that has passed through the first metal layer ML1 among the light generated by the light-emitting element 10. Accordingly, the signal wires TL may improve light emission efficiency of the display device.

The signal wires TL may each include the first metal layer ML1, the second metal layer ML2 disposed under the first metal layer ML1, and the third metal layer ML3 disposed under the second metal layer ML2. Alternatively, the signal wires TL may each further include the fourth metal layer ML4 disposed under the third metal layer ML3, and the fifth metal layer ML5 disposed under the fourth metal layer ML4. At this time, the second metal layer ML2 may be formed of a material with a higher light reflectivity than the first and third metal layers ML1 and ML3. For example, the second metal layer ML2 may include aluminum (Al) or silver (Ag).

In addition, the signal wires TL implement various metal stack structures using metal materials of different materials, thicknesses, etc., like the first electrode 161, so that the resistance of the signal wires TL can be adjusted.

Accordingly, in the display device according to the present disclosure, the light emitted from the light-emitting element 10 is reflected by the signal wires TL together with the first electrode 161, thereby further improving the light emission efficiency of the display device. Accordingly, in the display device according to the present disclosure, as the light emission efficiency of the light-emitting element 10 is improved by an increase in the reflection area, the display device can be driven with a low power and thus improved to meet requirements such as low power consumption and high efficiency. In addition, in the display device according to the present disclosure, various wire designs become possible by adjusting the material, thickness, etc., of each of the plurality of metal layers in accordance with the disclosure of the light-emitting element 10.

The display device according to an embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation device, a vehicle display device, a theater display device, a television, a wallpaper device, a signage device, a gaming device, a notebook, a monitor, a camera, a camcorder, and home appliances. Also, the display device according to one or more embodiments of the present disclosure can be applied to an inorganic light-emitting lighting device.

A display device according to one or more embodiments of the present disclosure may be described as follows.

A display device according to one or more embodiments of the present disclosure includes an insulating layer disposed on a substrate; a plurality of first electrodes and contact electrodes disposed on the insulating layer; a plurality of light-emitting elements disposed on the plurality of first electrodes; a second electrode disposed on the plurality of light-emitting elements; and a passivation layer covering the first electrode, wherein the passivation layer has a first opening hole exposing a portion of an upper surface of the first electrode.

The insulating layer may be an organic material, and the passivation layer may be an inorganic material.

The passivation layer may have a second opening hole exposing a portion of the insulating layer.

The display device may further include a plurality of bank patterns disposed between the insulating layer and the plurality of first electrodes.

The second opening hole may be disposed between the plurality of bank patterns.

An area of the insulating layer may be 4 to 5 times an entire area of the plurality of second opening holes.

A horizontal area of the first electrode may be 8 to 10 times a horizontal area of the first opening hole.

The first electrode may include a first metal layer, a second metal layer disposed under the first metal layer, and a third metal layer disposed under the second metal layer, wherein a light reflectivity of the second metal layer may be greater than a light reflectivity of the first and third metal layers.

The second metal layer may contain aluminum.

A thickness of the second metal layer may be greater than a thickness of the third metal layer.

The first electrode may further include a fourth metal layer disposed under the third metal layer, and a fifth metal layer disposed under the fourth metal layer, wherein the fourth metal layer may be made of a same material as the second metal layer, and the fifth metal layer may be made of a same material as the third metal layer.

A thickness of the fourth metal layer may be greater than a thickness of the second metal layer.

A thickness of the second metal layer may be smaller than or equal to a thickness of the third metal layer.

The fifth metal layer may contain titanium.

The display device may further include a plurality of signal wires extending between the plurality of bank patterns and connected to the plurality of first electrodes, wherein the signal wire may include a same metal layer as the first electrode.

The signal wire may include a first metal layer, a second metal layer disposed under the first metal layer, and a third metal layer disposed under the second metal layer, wherein a light reflectivity of the second metal layer may be greater than a light reflectivity of the first and third metal layers.

The display device may further include a plurality of connection wires disposed between the substrate and the insulating layer, and a pixel driving circuit connected to the plurality of connection wires, wherein the plurality of connection wires may be electrically connected to the plurality of first electrodes and the contact electrode.

The pixel driving circuit may be a driving driver.

The second electrode may be arranged in each pixel row as a plurality of second electrodes spaced apart from each other, and the plurality of second electrodes may be each electrically connected to the contact electrode.

The display device may further include a solder pattern disposed in the first opening hole to electrically connect the first electrode and the light-emitting element.

The plurality of light-emitting elements may be inorganic light emitting diodes.

A display device according to one or more embodiments of the present disclosure includes an insulating layer disposed on a substrate; a plurality of first electrodes and contact electrodes disposed on the insulating layer; a passivation layer covering the first electrode while exposing a portion of the first electrode; a plurality of light-emitting elements disposed on the plurality of first electrodes; a solder pattern disposed between the first electrode and the light-emitting element; and a second electrode disposed on the plurality of light-emitting elements, wherein the first electrode includes a first metal layer in contact with the solder pattern, a second metal layer disposed under the first metal layer, and a third metal layer disposed under the second metal layer, and wherein a light reflectivity of the second metal layer may be greater than a light reflectivity of the first and third metal layers.

A thickness of the second metal layer may be greater than a thickness of the third metal layer.

The first electrode may further include a fourth metal layer disposed under the third metal layer, and a fifth metal layer disposed under the fourth metal layer, wherein the fourth metal layer may be made of a same material as the second metal layer, and the fifth metal layer may be made of a same material as the third metal layer.

A thickness of the fourth metal layer may be greater than a thickness of the second metal layer.

A thickness of the second metal layer may be smaller than or equal to a thickness of the third metal layer.

The display device may further include a plurality of bank patterns disposed between the insulating layer and the plurality of first electrodes, and a plurality of signal wires extending between the plurality of bank patterns and connected to the plurality of first electrodes, wherein the signal wire may include a same metal layer as the first electrode.

The passivation layer may have a first opening hole exposing the first electrode.

The first opening hole exposes an entire upper surface of the first electrode.

The passivation layer has a second opening hole exposing a portion of the insulating layer.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

### DESCRIPTION OF REFERENCE NUMERALS

10: Light-emitting element
20: Pixel driving circuit
110: Substrate
121: Buffer layer
122: Insulating layer
130: Bank pattern
141: First optical layer
142: Second optical layer
161: First electrode
163: Contact electrode
170: Second electrode

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
an insulating layer disposed on a substrate;
a plurality of first electrodes and contact electrodes disposed on the insulating layer;
a plurality of light-emitting elements disposed on the plurality of first electrodes;
a second electrode disposed on the plurality of light-emitting elements;
a passivation layer covering the first electrode; and
a first opening hole at the passivation layer, the first opening hole extends through the passivation layer,
wherein the passivation layer does not cover an upper surface of the first electrode at the first opening hole.

2. The display device of claim 1, wherein the insulating layer is an organic material, and the passivation layer is an inorganic material.

3. The display device of claim 2, further comprising: a second opening hole at the passivation layer, the second opening hole extending through the passivation layer,
wherein the passivation layer does not cover a portion of the insulating layer at the second opening hole.

4. The display device of claim 3, further comprising:
a plurality of bank patterns disposed between the insulating layer and the plurality of first electrodes.

5. The display device of claim 4, wherein the second opening hole is disposed between the plurality of bank patterns.

6. The display device of claim 5, wherein an area of the insulating layer is 4 to 5 times an entire area of the plurality of second opening holes.

7. The display device of claim 1, wherein a horizontal area of the first electrode is 8 to 10 times a horizontal area of the first opening hole.

8. The display device of claim 1, wherein the first electrode includes:
a first metal layer,
a second metal layer disposed under the first metal layer, and
a third metal layer disposed under the second metal layer,
wherein a light reflectivity of the second metal layer is greater than a light reflectivity of the first and third metal layers.

9. The display device of claim 8, wherein the second metal layer contains aluminum.

10. The display device of claim 9, wherein a thickness of the second metal layer is greater than a thickness of the third metal layer.

11. The display device of claim 8, wherein the first electrode further includes a fourth metal layer disposed under the third metal layer, and a fifth metal layer disposed under the fourth metal layer,
the fourth metal layer is made of a same material as the second metal layer, and
the fifth metal layer is made of a same material as the third metal layer.

12. The display device of claim 11, wherein a thickness of the fourth metal layer is greater than a thickness of the second metal layer.

13. The display device of claim 11, wherein a thickness of the second metal layer is smaller than or equal to a thickness of the third metal layer.

14. The display device of claim 11, wherein the fifth metal layer contains titanium.

15. The display device of claim 4, further comprising:
a plurality of signal wires extending between the plurality of bank patterns and connected to the plurality of first electrodes,
wherein the signal wire includes a same metal layer as the first electrode.

16. The display device of claim 15, wherein the signal wire includes:
a first metal layer,
a second metal layer disposed under the first metal layer, and
a third metal layer disposed under the second metal layer,
wherein a light reflectivity of the second metal layer is greater than a light reflectivity of the first and third metal layers.

17. The display device of claim 1, further comprising:
a plurality of connection wires disposed between the substrate and the insulating layer, and
a pixel driving circuit connected to the plurality of connection wires,
wherein the plurality of connection wires are electrically connected to the plurality of first electrodes and the contact electrode.

18. The display device of claim 17, wherein the pixel driving circuit is a driving driver.

19. The display device of claim 1, wherein the second electrode is arranged in each pixel row as a plurality of second electrodes spaced apart from each other, and
the plurality of second electrodes are each electrically connected to the contact electrode.

20. The display device of claim 1, further comprising:
a solder pattern disposed in the first opening hole to electrically connect the first electrode and the light-emitting element.

21. The display device of claim 1, wherein the plurality of light-emitting elements are inorganic light emitting diodes.

22. A display device comprising:
an insulating layer disposed on a substrate;
a plurality of first electrodes and contact electrodes disposed on the insulating layer;
a passivation layer covering the first electrode while exposing a portion of the first electrode;
a plurality of light-emitting elements disposed on the plurality of first electrodes;
a solder pattern disposed between the first electrode and the light-emitting element; and
a second electrode disposed on the plurality of light-emitting elements,
wherein the first electrode includes a first metal layer in contact with the solder pattern, a second metal layer disposed under the first metal layer, and a third metal layer disposed under the second metal layer,
wherein a light reflectivity of the second metal layer is greater than a light reflectivity of the first and third metal layers.

23. The display device of claim 22, wherein a thickness of the second metal layer is greater than a thickness of the third metal layer.

24. The display device of claim 22, wherein the first electrode further includes a fourth metal layer disposed under the third metal layer, and a fifth metal layer disposed under the fourth metal layer,
the fourth metal layer is made of a same material as the second metal layer, and
the fifth metal layer is made of a same material as the third metal layer.

25. The display device of claim 24, wherein a thickness of the fourth metal layer is greater than a thickness of the second metal layer.

26. The display device of claim 24, wherein a thickness of the second metal layer is smaller than or equal to a thickness of the third metal layer.

27. The display device of claim 22, further comprising:
a plurality of bank patterns disposed between the insulating layer and the plurality of first electrodes, and a plurality of signal wires extending between the plurality of bank patterns and connected to the plurality of first electrodes,
wherein the signal wire includes a same metal layer as the first electrode.

28. The display device of claim 22, wherein the passivation layer has a first opening hole exposing the first electrode.

29. The display device of claim 28, wherein the first opening hole exposes an entire upper surface of the first electrode.

30. The display device of claim 28, wherein the passivation layer has a second opening hole exposing a portion of the insulating layer.

31. A display device comprising:
a light-emitting element;
a bank pattern overlapping the light-emitting element from a plan view;
a first electrode between the light-emitting element and the bank pattern;
an insulating layer on a substrate, the insulating layer having a first surface and a second surface opposite the first surface, the second surface facing the substrate;
a passivation layer on the first electrode, the bank pattern, and the insulating layer; and
a first opening extending through the passivation layer,
wherein the first surface of the insulating layer includes a portion that is not covered by the passivation layer,
wherein the portion of the insulating layer and the first opening overlaps each other from a plan view.

32. The display device of claim 31, further comprising:
a second opening extending through the passivation layer, the second opening and the first opening at a different location from each other;
a solder pattern disposed between the first electrode and the light-emitting element,
wherein the second opening and the solder pattern overlap each other from a plan view.

33. The display device of claim 32, further comprising:
at least one signal wire adjacent to the bank pattern,
wherein the at least one signal wire is disposed on and contacts the insulating layer.

34. The display device of claim 32, wherein the passivation layer continuously and contiguously extends from an upper surface of the first electrode to the first surface of the insulating layer.

35. The display device of claim 34, further comprising:
at least one signal wire adjacent to the bank pattern,
wherein the passivation layer is disposed on the upper surface of the first electrode, a side surface of the bank pattern, and an upper surface and side surfaces of the at least one signal wire.

36. The display device of claim 31, wherein the first electrode includes:
a first metal layer;
a second metal layer; and
a third metal layer,
wherein the second metal layer is between the first metal layer and the second metal layer,
wherein a light reflectivity of the second metal layer is greater than a light reflectivity of the first and third metal layers, and
wherein the first metal layer is closer to the light-emitting element than the second metal layer.

37. The display device of claim 36, wherein the first electrode further includes:
a fourth metal layer; and
a fifth metal layer,
wherein the fourth metal layer contacts the third metal layer,
wherein the fourth metal layer is made of a same material as the second metal layer, and
wherein the fifth metal layer is made of a same material as the third metal layer.

38. The display device of claim 31, further comprising:
at least one signal wire adjacent to the bank pattern and the light-emitting element,
wherein the passivation layer is disposed on the upper surface of the first electrode, a side surface of the bank pattern, and an upper surface and side surfaces of the at least one signal wire.

39. The display device of claim 38, wherein the at least one signal wire includes:
a first metal layer;
a second metal layer; and
a third metal layer,
wherein the second metal layer is between the first metal layer and the second metal layer,
wherein a light reflectivity of the second metal layer is greater than a light reflectivity of the first and third metal layers, and
wherein the third metal layer is closer to the insulating layer than the second metal layer.

40. The display device of claim 39, wherein the at least one signal wire further includes:
a fourth metal layer; and
a fifth metal layer,
wherein the fourth metal layer contacts the third metal layer,
wherein the fourth metal layer is made of a same material as the second metal layer, and
wherein the fifth metal layer is made of a same material as the third metal layer.
